(19) United States
(12) Patent Application Publication
(10) Pub. No.: US 2026/0287696 A1
(43) Pub. Date: Sep. 24, 2026

(54) SYSTEMS, APPARATUSES, AND METHODS FOR DETERMINING SCAN PARAMETERS

(71) Applicant: Siemens Healthineers AG, Forchheim (DE)

(72) Inventors: Gregor Körzdörfer, Marburg (DE); Mathias Nittka, Baiersdorf (DE); Venkata Veerendranadh Chebrolu, Rochester, MN (US)

(21) Appl. No.: 19/083,641

(22) Filed: Mar. 19, 2025

(51) Int. Cl. G01R 33/54; G01R 33/565

(52) U.S. Cl. CPC G01R 33/543; G01R 33/56563

(57) ABSTRACT

A system for determining scan parameters includes at least one memory configured to store instructions and at least one processor configured to execute the instructions to cause the system to perform a distortion mapping sequence to generate a field map, process the field map by calculating at least one of a gradient or a higher order derivative of the field map, and determine the scan parameters based on the field map and the at least one of the gradient or the higher order derivative of the field map. The field map includes spatial information related to anticipated distortions caused by variations of a static magnetic field.

### TECHNICAL FIELD

The present disclosure relates to systems, apparatuses, and/or methods for determining scan parameters.

### BACKGROUND

Magnetic field distortion levels are known to impact image quality in medical imaging. Magnetic field distortion may be caused by metal implants and may be unique to each patient.

### SUMMARY

At least one example embodiment relates to a system for determining scan parameters, the system may include at least one memory configured to store instructions and at least one processor configured to execute the instructions to cause the system to perform a distortion mapping sequence to generate a field map, process the field map by calculating at least one of a gradient or a higher order derivative of the field map, and determine the scan parameters based on the field map and the at least one of the gradient or the higher order derivative of the field map. The field map may include spatial information related to anticipated distortions caused by variations of a static magnetic field.

In at least one example embodiment, the scan parameters may include at least one of a phase encoding direction, a frequency encoding direction, a slice encoding direction, a type of fat-saturation, a scan prioritization, or B0 and B1 shimming parameters. The type of fat-saturation may include at least one of short tau inversion recovery (“STIR”) or spectral-fat-saturation and the scan prioritization may include spectral coverage or slice coverage.

In at least one example embodiment, the at least one processor may be configured to execute the instructions to further cause the system to generate a localizer image based on a localizer scan; and generate a graphical representation of the field map by overlaying the at least one of the gradient or the higher order derivative of the field map on the localizer image.

In at least one example embodiment, the at least one processor may be further configured to cause the system to determine the scan parameters by determining mean field map gradients in each of an x-direction, y-direction and z-direction and assigning at least one of a phase encoding direction, a frequency encoding direction, or a slice encoding direction based on the mean field map gradients. In at least one example embodiment, the at least one processor may be further configured to cause the system to determine the mean field map gradients based on a weighting function.

In at least one example embodiment, the at least one processor may be further configured to cause the system to compare the field map to a plurality of stored field maps in a database and determine the scan parameters based on the comparison of the field map to the plurality of stored field maps in the database.

In at least one example embodiment, the at least one processor may be further configured to cause the system to compare the at least one of the gradient or the higher order derivative of the field map to a plurality of gradients and higher order derivatives of field maps in a database. In at least one example embodiment, the at least one processor may be further configured to cause the system to determine the scan parameters based on the comparison of the at least one of the gradient or the higher order derivative of the field map to the plurality of gradients and the higher order derivatives of field maps in the database.

In at least one example embodiment, the at least one processor may be further configured to cause the system to output at least one distortion forecast map. The at least one distortion map may illustrate an expected impact of metal distortions based on various options for the scan parameters. In at least one example embodiment, the at least one processor may be further configured to cause the system to determine the scan parameters based on the at least one distortion forecast map.

In at least one example embodiment, the at least one processor may be further configured to cause the system to perform a scan using the scan parameters. The scan parameters may be configured to mitigate one or more metal distortion levels of an image output of the scan.

Also described herein is a method for determining scan parameters. The method may include performing a distortion mapping sequence to generate a field map, processing the field map by calculating at least one of a gradient or a higher order derivative of the field map, and determining the scan parameters based on the field map and the at least one of the gradient or the higher order derivative of the field map. The field map may include spatial information related to anticipated distortions caused by variations of a static magnetic field.

In at least one example embodiment, the scan parameters may include at least one of a phase encoding direction, frequency encoding direction, slice encoding directions, a type of fat-saturation, a scan prioritization, or B0 and B1 shimming parameters. The type of fat-saturation may include at least one of short tau inversion recovery (“STIR”) or spectral-fat-saturation and the scan prioritization may include spectral coverage or slice coverage.

In at least one example embodiment, the method may further include generating a localizer image based on a localizer scan and generating a graphical representation of the field map by overlaying the at least one of the gradient or the higher order derivative of the field map on the localizer image.

In at least one example embodiment, the determining the scan parameters may include determining mean field map gradients in each of an x-direction, y-direction and z-direction and assigning at least one of a phase encoding direction, a frequency encoding direction, or a slice encoding direction based on the mean field map gradients. In at least one example embodiment, the determining the mean field map gradients may be based on a weighting function.

In at least one example embodiment, the method may further include comparing the field map to a plurality of stored field maps in a database and determining the scan parameters based on the comparison of the field map to the plurality of stored field maps in the database.

In at least one example embodiment, the method may further include comparing the at least one of the gradient or the higher order derivative of the field map to a plurality of gradients and higher order derivatives of field maps in a database. In at least one example embodiment, the determining the scan parameters may be further based on the comparison of the at least one of the gradient or the higher order derivative of the field map to the plurality of gradients and higher order derivatives of field maps in the database.

In at least one example embodiment, the method may further include outputting at least one distortion forecast map, the at least one distortion forecast map illustrating an expected impact of metal distortions based on various options for the scan parameters. In at least one example embodiment, the determining the scan parameters may be further based on the at least one distortion forecast map.

In at least one example embodiment, the method may further include performing a scan using the scan parameters, wherein the scan parameters are configured to mitigate one or more metal distortion levels of an image output of the scan.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1A is an illustration of a system for implementing methods according to example embodiments.

FIG. 1B is a block diagram illustrating an example embodiment of the system shown in FIG. 1A.

FIG. 2 illustrates a field map in accordance with at least one example embodiment.

FIG. 3 illustrates a gradient of the field map of FIG. 2 in the y-direction in accordance with at least one example embodiment.

FIG. 4 illustrates a gradient of the field map of FIG. 2 in the x-direction in accordance with at least one example embodiment.

FIG. 5 illustrates a localizer scan in accordance with at least one example embodiment.

FIG. 6 illustrates a method for determining scan parameters in accordance with at least one example embodiment.

FIG. 7 illustrates a step of processing the field map of the method of FIG. 6 in accordance with at least one example embodiment.

FIG. 8 illustrates a step of determining scan parameters based on the field map of the method of FIG. 6 in accordance with at least one example embodiment.

### DETAILED DESCRIPTION OF EXAMPLE EMBODIMENTS

Independent of the grammatical term usage, individuals with male, female or other gender identities are included within the term.

Some detailed example embodiments are disclosed herein. However, specific structural and functional details disclosed herein are merely representative for purposes of describing some example embodiments. Example embodiments may, however, be embodied in many alternate forms and should not be construed as limited to only example embodiments set forth herein.

Accordingly, while example embodiments are capable of various modifications and alternative forms, example embodiments thereof are shown by way of example in the drawings and will herein be described in detail. It should be understood, however, that there is no intent to limit an example embodiment to the particular forms disclosed, but to the contrary, example embodiments are to cover all modifications, combinations, equivalents, and alternatives falling within the scope of an example embodiment. Like numbers refer to like elements throughout the description of the figures.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, region, layer, or section discussed below could be termed a second element, region, layer, or section without departing from the teachings of example embodiment.

The terminology used herein is for the purpose of describing various example embodiment only and is not intended to be limiting of example embodiment. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, and/or elements, but do not preclude the presence or addition of one or more other features, integers, steps, operations, elements and/or groups thereof.

When the words “about” and “substantially” are used in this specification in connection with a numerical value, it is intended that the associated numerical value include a tolerance of ±10% around the stated numerical value, unless otherwise explicitly defined. Moreover, when the terms “generally” or “substantially” are used in connection with geometric shapes, it is intended that precision of the geometric shape is not required but that latitude for the shape is within the scope of the disclosure. Furthermore, regardless of whether numerical values or shapes are modified as “about,” “generally,” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which example embodiment belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Metallic implants in patients may lead to off-resonances that can cause magnetic resonance (“MR”) imaging artifacts and/or distortions. Several MR imaging techniques are available to mitigate artifacts and distortion. However, generally information about an implant is unavailable and thus an operator must choose a best scanning strategy based only on their prior experience or based on a localizer scan which leads to imaging strategies that may not be optimized for a particular patient. When choosing an imaging approach and scan parameters, it is important to determine an optimal phase encoding direction, frequency encoding direction, and slice encoding direction. Artifacts induced by off-resonances from metallic implants for example may present differently depending on the phase encoding direction, frequency encoding direction, and slice encoding direction that are used for the imaging because locally different off-resonances may lead to different shifts present in resultant images. In at least one example embodiment, a readout encoding direction may suffer from displaced voxels due to off-resonances and selective pulses, such as slice selective pulses, may be affected by a varying off-resonance in the readout encoding direction. Thus, phase encoding may be a robust technique to addressing locally varying off-resonances. The systems and methods described herein enable an operator to adapt the encoding directions described above in an optimal way so that regions of high diagnostic relevance are least impacted by artifacts caused by metal implants.

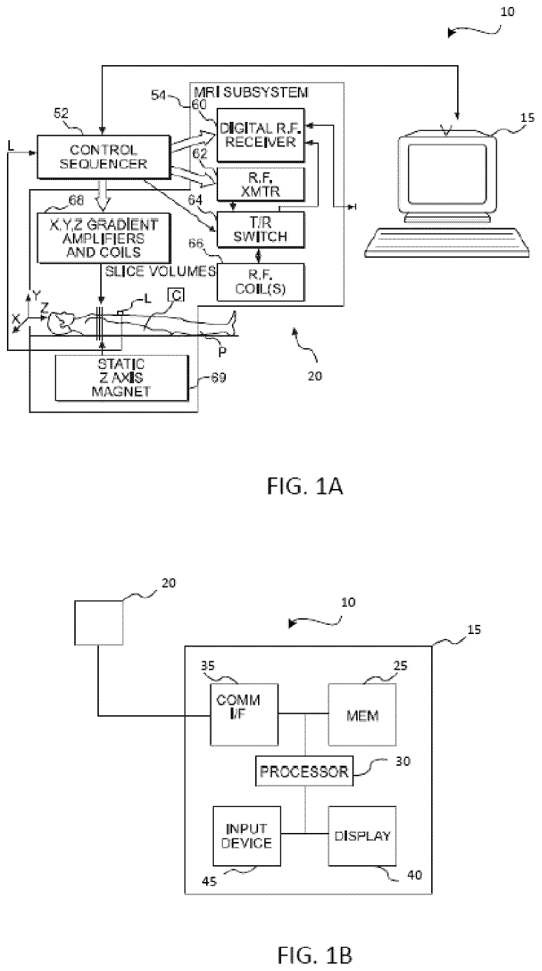

FIG. 1A is an illustration of a system for implementing methods according to example embodiments described herein. FIG. 1B is a block diagram illustrating an example embodiment of the system shown in FIG. 1A. Although one or more example embodiments may be described herein with regard to the systems shown in FIGS. 1A and 1B, example embodiments should not be limited to these examples.

Referring to FIGS. 1A and 1B, a system 10 may include an information processing device 15 and an acquisition device 20. The acquisition device 20 includes a magnetic resonance imaging (“MRI”) real-time control sequencer 52 and an MRI subsystem 54. The MRI subsystem 54 may include XYZ magnetic gradient coils and associated amplifiers 68, a static Z-axis magnet 69, a digital radiofrequency (“RF”) transmitter 62, a digital RF receiver 60, a transmit/receive switch 64, and RF coil(s) 66. The acquisition device 20 may include additional or fewer components in some example embodiments, and may be configured to image a patient.

The MRI subsystem 54 may be controlled in real-time by the MRI real-time control sequencer 52 to generate and measure magnetic field and radio frequency emissions that stimulate nuclear magnetic resonance (“NMR”) phenomena in an object P (e.g., a human or other living body) to be imaged.

The information processing device 15 may implement a method for processing medical data, such as medical image data. As discussed in more detail below, one or more information processing devices such as the information processing device 15 may be configured to implement any or all of the example embodiments described herein.

In FIGS. 1A and 1B, the acquisition device 20 is shown as a separate unit from the information processing device 15. It is, however, possible to integrate the information processing device 15 as part of the acquisition device 20.

The information processing device 15 may include at least one memory 25, processing circuitry including at least one processor 30, at least one communication interface 35 and/or an input device 40. The at least one memory 25 may include various special purpose program code including computer executable instructions which may cause the at least one processor 30 of the information processing device 15 to perform one or more of the methods according to example embodiments described herein. The acquisition device 20 may provide the medical data to the information processing device 15 via the input device 40. In some example embodiments, the information processing device 15 may additionally include a display 45 that may be configured to output information about one or more of an imaging process, the information processing device 15, or the acquisition device 20.

As will be appreciated, depending on the implementation of the system 10, the system 10 may include additional components. However, it is not necessary that all of these generally conventional components be shown in order to disclose the illustrative example embodiment. For example purposes, the system 10 will be discussed with regard to the at least one processor 30. However, it should be understood that the system 10 may include one or more processors or other processing circuitry, such as one or more Application Specific Integrated Circuits (“ASICs).

The at least one processor 30 may include, but is not limited to, a central processing unit (“CPU”), an arithmetic logic unit (“ALU”), a graphics processing unit (“GPU”), an application processor (“AP”), a digital signal processor (“DSP”), a microcomputer, a field programmable gate array (“FPGA”), and programmable logic unit, ASIC, a neural network processing unit (“NPU”), an Electronic Control Unit (“ECU”), a quantum computer, and the like. In some example embodiments, the processing circuitry may include a non-transitory computer readable storage medium or device (e.g., memory), for example a solid state drive (“SSD”), storing a program of instructions, and a processor (e.g., CPU) configured to execute the program of instructions to implement the functionality and/or methods performed by some or all of the systems according to any of the example embodiments.

The at least one memory 25 may be a computer readable storage medium that generally includes a random access memory (“RAM”), read only memory (“ROM”), and/or a permanent mass storage device, such as a disk drive. The at least one memory 25 may also store an operating system and any other routines/modules/applications for providing the functionalities of the system 10 to be executed by the at least one processor 30. These software components may also be loaded from a separate computer readable storage medium into the at least one using a drive mechanism (not shown). Such separate computer readable storage medium may include a disc, tape, DVD/CD-ROM drive, memory card, or other like computer readable storage medium (not shown). In some example embodiments, software components may be loaded into the at least one memory 25 via one of the at least one communication interface 35, rather than via a computer readable storage medium.

The at least one processor 30 or other processing circuitry may be configured to carry out instructions of a computer program by performing the arithmetical, logical, and input/output operations of the system. Instructions may be provided to the at least one processor 30 by the at least one memory 25.

The at least one communication interface 35 may be wired and may include components that interface the at least one processor 30 with the other input/output components. As will be understood, the at least one communication interface 35 and programs stored in the at least one memory 25 to set forth the special purpose functionalities of the system 10 will vary depending on the implementation of the system 10.

The at least one communication interface 35 may also include one or more user input devices (e.g., a keyboard, a keypad, a mouse, or the like) and user output devices (e.g., a display, a speaker, or the like).

As disclosed herein, the term “storage medium,” “computer readable storage medium” or “non-transitory computer readable storage medium” may represent one or more devices for storing data, including ROM, RAM, magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing or carrying instruction(s) and/or data.

Furthermore, example embodiments may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store a computer program or computer program code, and the at least one memory and the computer program code may be configured to, with at least one processor, the methods described herein. Additionally, the processor, memory and example algorithms, encoded as computer program code, serve as means for providing or causing performance of operations discussed herein. At least one other example embodiment may include a computer program including program segments or instructions that, when executed by at least one processor of a system, cause the system to perform the functions and methods described herein.

A code segment of a computer program may represent a procedure, function, subprogram, program, routine, subroutine, module, software package, class, or any combination of instructions, data structures or program statements. A code segment may be coupled to another code segment or a hardware circuit by passing and/or receiving information, data, arguments, parameters or memory contents. Information, arguments, parameters, data, etc. may be passed, forwarded, or transmitted via any suitable technique including memory sharing, message passing, token passing, network transmission, etc.

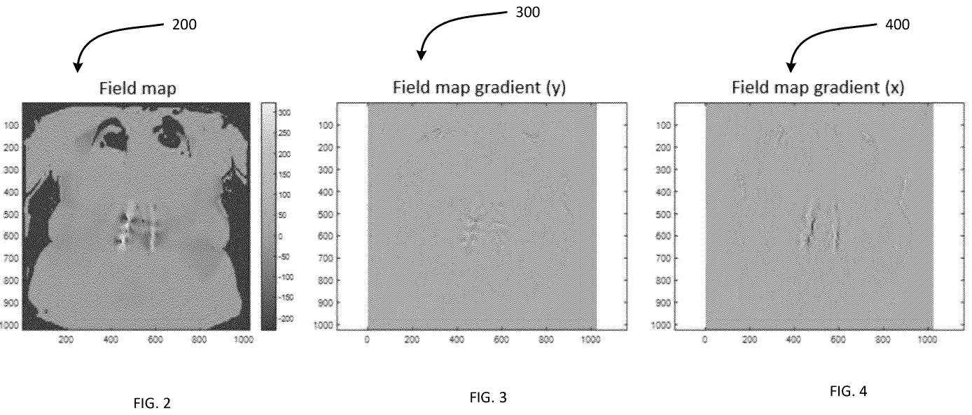

FIG. 2 is an example of a field map 200 that may be generated as part of a distortion mapping sequence. The distortion mapping sequence may scan a desired portion of a patient to calculate an off-resonance map. An off-resonance map may also be referred to as a field map and/or a B0-map of a local static magnetic field. In the context of imaging patients with implants, off-resonance is caused by a susceptibility gradient between the implant and human tissue.

In particular, the distortion mapping sequence may begin by measuring a static magnetic field of the desired portion of the patient to obtain a field map. In at least one example embodiment, the field map may include spatial information related to anticipated distortions caused by variations of a static magnetic field. Mapping the static magnetic field may result in a B0-map. Details of an example of a method of mapping a static magnetic field may be found in Kaushik SS, Marszalkowski C, Koch KM. External calibration of the spectral coverage for three-dimensional multispectral MRI. Magn Reson Med. 2016; 76(5): 1494-1503. doi:10.1002/mrm.26065 which is incorporated herein by reference in its entirety. An example method of mapping a static magnetic field may use spectrally selective RF pulses to excite several frequency bins separately and acquire a signal of each bin individually. Images of each of the frequency bins may be used to generate a field map and may be composed to form an image. In at least one example embodiment, the static magnetic field may be distorted by an implant in or near the desired portion of the patient to be imaged. In at least one example embodiment, the implant may be a metal implant.

As shown in FIG. 2, the field map 200 is of a subject's lungs and core region. The x-axis and the y-axis represent a number of pixels of the image. The field map 200 may be a 1000 by 1000 pixel image. The variation in color or intensity of the field map 200 represents an inhomogeneity of the image. The scale represents a level of inhomogeneity that includes both positive and negative inhomogeneity values. The level of inhomogeneity is generally represented in Hertz (Hz). Here, the scale is shown as Hz/10. When analyzing a field map, an absolute value of inhomogeneity may be analyzed to determine which regions include a large inhomogeneity. As shown in the field map 200, a central region shows a large inhomogeneity. This region may include one or more metallic implants or objects.

In at least one example embodiment, the field map may be processed by calculating a gradient or higher order derivative that may be used with the field map to determine scan parameters for imaging of the patient. A gradient or higher order derivative of a field map illustrates a difference between a pixel or voxel and its surrounding pixels or voxels. A gradient or higher order derivative may be calculated by a known method in the art. In at least one example embodiment, various gradient operators such as the Sobel operator, Prewitt operator, Roberts cross operator, or more advanced methods like the Hessian matrix may be used to calculate the gradient or the higher order derivative of the field map, depending on the desired level of detail and computational complexity. These methods are configured to identify edges and intensity changes within an image which may enable feature extraction in medical image analysis.

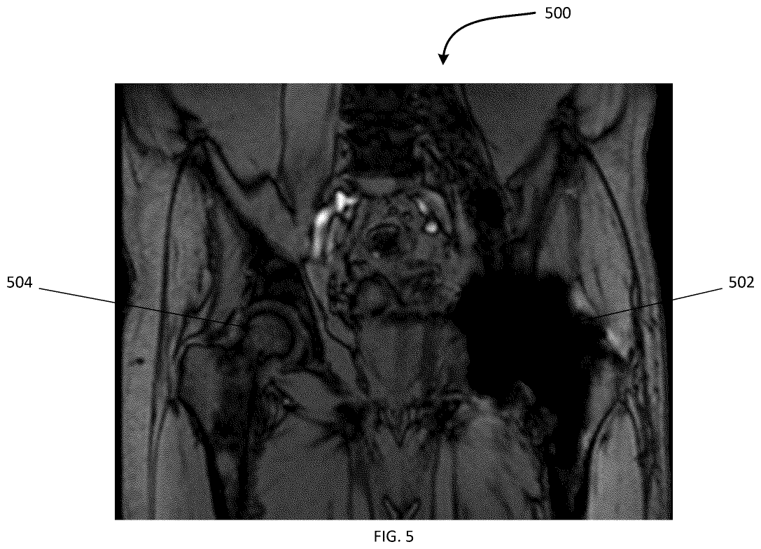

FIG. 3 illustrates a field map gradient 300 in the y-direction and FIG. 4 illustrates a field map gradient 400 in the x-direction for the field map 200. Similar to FIG. 2, the x-axis and the y-axis of FIG. 3 and FIG. 4 represent a number of pixels. In at least one example embodiment, a mean field map gradient may be determined by calculating a mean or an average of the gradients in a particular direction. For example, a mean field map gradient for the field map gradient 300 in the y-direction is an average of the gradients for each pixel of the field map gradient 300 in the y-direction. A mean of the field map gradient 300 in the y-direction is 0.3374 while a mean of the field map gradient 400 in the x-direction is 0.5205. As illustrated in FIGS. 3 and 4, the gradient along the x-direction is stronger than the gradient along the y-direction. Thus, scan parameters for an imaging protocol may be based on the determination that the gradient along the x-direction is stronger than the gradient along the y-direction. In particular, a readout encoding direction and a phase encoding direction may be adjusted based on the stronger gradient along the x-direction. FIGS. 2-4 illustrate a 2-dimensional field map and its associated gradients. Example embodiments are not limited herein and field maps and derivatives or higher order gradients may be determined for 2-dimensional or 3-dimensional embodiments.

In at least one example embodiment, a mean field map gradient calculation may include a weighting function. For example, pixels closer to a central region of an image may be weighted higher than pixels closer to an edge of the image. For example, a radius may be defined from a center of an image and each pixel within the radius may be considered or given a weight of one which all pixels outside of the radius may be excluded or given a weight of zero. Alternative weighting functions may be applied if different regions or pixels or voxels should be given more or less consideration for a particular field map.

In at least one example embodiment, scan parameters may be determined based on the field map and the gradient or higher order derivatives of the field map. Further, in at least one example embodiment, the scan parameters may be determined based on mean field map gradients in each of the x-direction, y-direction, and z-direction for a 3-dimensional field map. The scan parameters may include a phase encoding direction, a frequency encoding direction, a slice encoding direction, a type of fat-saturation such as short tau inversion recovery (“STIR”) or spectral fat saturation, a determination of where to invest scan time such as prioritizing more spectral coverage or more slice coverage with 2-dimensional and 3-dimensional multi-spectral imaging (“MSI”) methods, and B0 and B1 shimming parameters. In at least one example embodiment, B0 parameters may be configured to homogenize a magnetic field when performing an imaging procedure and B1 parameters may be configured to homogenize an RF profile. In at least one example embodiment, at least a phase encoding direction, a frequency encoding direction, or a slice encoding direction may be determined based on the mean field map gradients.

In at least one example embodiment, STIR fat suppression may be used when imaging around implants and spectral fat saturation may be used to suppress fat signal in musculoskeletal MRI. However, spectral fat saturation may fail when there is B0 field inhomogeneity that may be detected by a field map. In particular, spectral fat saturation may fail when there are large gradients in a field map. If the field map is smooth, spectral fat saturation may be used and may work with adaptive spectral fat saturation options such as dynamic fat saturation or sophisticated harmonic artifact reduction for phase (“SHARP”) that are configured to adapt a spectral profile of the RF pulses. A field map may be considered smooth when a gradient of the field map is relatively uniform or has a low level of inhomogeneity. In at least one example embodiment, a field map with an inhomogeneity of each pixel between −100 Hz and 100 Hz may be considered smooth or to have a low inhomogeneity. In at least one example embodiment, a magnitude of the inhomogeneity may be analyzed. Thus, an absolute value or a magnitude of inhomogeneity of less than about 100 Hz may be considered low inhomogeneity. Thus, if a field map indicates low inhomogeneity this may indicate that a patient does not have an implant or that the implant is ceramic which may enable use of standard spectral fat saturation methods. If the field map indicates low and/or moderate inhomogeneities this may indicate that an implant is present and the implant may be ceramic or titanium. For low and/or moderate inhomogeneities, adaptive spectral fat saturation options may be used. Adaptive spectral fat saturation methods may also be used if the field-map values are high, but the gradients of field map are low, adaptive spectral fat sat options can be used. If both the absolute values of the field-map and the gradients of the field-map are high, then STIR fat suppression can be used.

In at least one example embodiment, a location of the gradients of the field map may be taken into consideration when determining the scan parameters. For example, there may be a field of interest or a region of interest of the patient to be imaged. Gradients within the field of interest may be weighted so that they are considered more important than gradients outside of the field of interest. Additionally or alternatively, gradients further from an isocenter of a field map may be less homogenous. The gradients may be weighted based on their locations from the isocenter.

In additional to the methods described above, in at least one example embodiment, scan parameters may be determined by comparing a field map to a database of field maps. The database of field maps may be stored in the at least one memory 25 or may be accessible by the at least one processor 30. Each field map of the database of field maps may include resultant images that include the scan parameters that were used for the imaging. Thus, the field map of a current scan may be compared to the database of field maps and a most similar field map from the database of field maps may be used to determine optimal scan parameters for the patient from which the current field map was generated. In at least one example embodiment, a deep learning, machine learning, or artificial intelligence algorithm such as a neural network may be used to perform the comparison. The algorithm may take the field map for the particular patient as an input with the field maps from the database and determine optimal parameters for a scan.

Similarly, in at least one example embodiment, scan parameters may be determined by comparing the gradient or higher order derivatives of the field map to gradients and higher order derivatives in a database. The gradients or higher order derivatives may be stored in the database of field maps or in a separate database that may be accessible by the at least one processor 30. The gradient or higher order derivative of a current field map may be compared to the database including gradients and higher order derivatives of field maps and a most similar gradient or higher order derivative from the database may be used to determine optimal scan parameters for the patient from which the current field map and gradient or higher order derivatives were generated. In at least one example embodiment, a deep learning, machine learning, or artificial intelligence algorithm such as a neural network may be used to perform the comparison. The algorithm may take the gradients or the higher order derivatives of the field map for the particular patient as an input with the gradients or the higher order derivatives from the database and determine optimal parameters for a scan such as an optimal frequency encode direction. In at least one example embodiment, the frequency encode direction should be chosen in a direction that has a minimal field inhomogeneity. For the example field map 200, the optimal frequency encode direction may be the y-direction because the x-direction has a larger inhomogeneity than the y-direction.

FIG. 5 illustrates a localizer image 500. In at least one example embodiment, before the distortion mapping sequence is performed a localizer scan may be performed to generate a localizer image of a scanned portion of the patient. The localizer scan may be performed by methods known in the art. The localizer image 500 illustrates a hip region of a subject. The subject has an implant in a first hip region 502 and no implant in a second hip region 504. The implant appears as a black area, void of features in the localizer image 500. In contrast, features of the second hip region 504 are visible in the localizer image 500.

The localizer scan may be used with the gradient or higher order derivatives of the field map to generate a graphical representation of the field map. For example, the gradient or higher order derivatives of the field map may be overlayed on the localizer image to generate the graphical representation of the field map. In at least one example embodiment, overlaying a gradient or higher order derivative of a field map on a localizer image may result in an image similar to the localizer image but with details of an inhomogeneity caused by the implant illustrated relative to the features captured in the localizer image 500. For example, the implant may appear highlighted or annotated in the first hip region 502 which may illustrate an inhomogeneity caused by the implant.

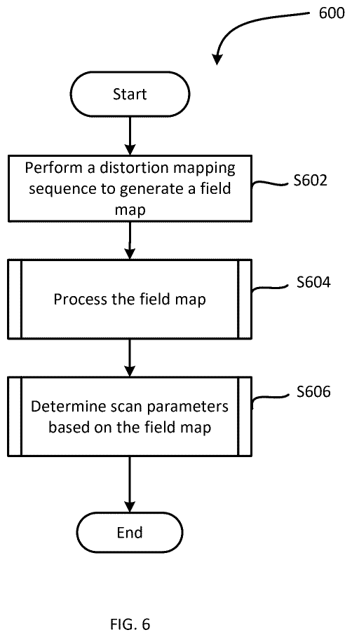

FIG. 6 is a flow chart of a method 600 for determining scan parameters. The method 600 is described herein with respect to the system 10 described in FIGS. 1A and 1B above. The method 600 may be configured to determine optimal scan parameters for a patient that may then be used to acquire an image of a field of interest or region of interest of the patient.

The method 600 may begin at S602 where the at least one processor 30 performs a distortion mapping sequence to generate a field map. Details of the generation of the field map are described above with respect to FIG. 2.

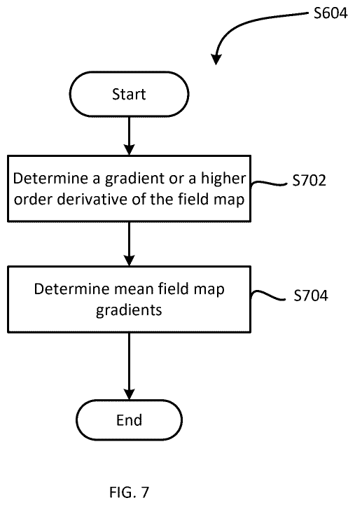

At S604 the at least one processor 30 may process the field map. Details of the processing of the field map are described below with reference to FIG. 7.

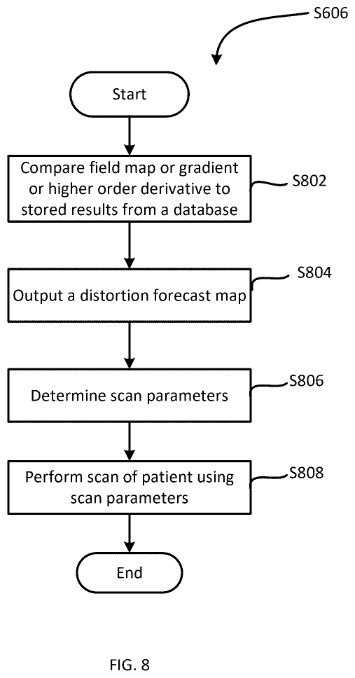

At S606, the at least one processor 30 may determine scan parameters based on the field map. In at least one example embodiment, the scan parameters may be determined based on the field map and a gradient or higher order derivative determined from the field map. In at least one example embodiment, at least a phase encoding direction, a frequency encoding direction, or a slice encoding direction may be scan parameters determined based on the mean field map gradients. Additional details of determining the scan parameters are described below with reference to FIG. 8.

FIG. 7 provides additional details of the step S604 of processing the field map of FIG. 6. At S702, the at least one processor 30 may determine a gradient or higher order derivative of the field map generated at S602. The gradient or higher order derivative may be determined as described above.

In at least one example embodiment, as described above, a graphical representation of the field map may be generated based on the gradient or higher order derivative of the field map. In particular, the graphical representation of the field map may be determined by overlaying the gradient or higher order derivative of the field map on a localizer image generated based on a localizer scan. This graphical representation of the field map may provide a visual output that may be analyzed by a user or physician to determine optimal scan parameters for a patient.

At S704, a mean field map gradient or a mean field map higher order derivative may optionally be determined from the gradient or higher order derivative of the field map. In at least one example embodiment, a mean field map gradient may be determined in each direction such that there is a mean field map gradient in the x-direction, the y-direction, and the z-direction for a 3-dimensional embodiment. As described above, in at least one example embodiment the mean field map gradients may be determined based on a weighting function. [gradient could be positive or negative-look at magnitude/abs value]

FIG. 8 provides additional details of the step S606 of determining scan parameters based on the field map of FIG. 6. At S802, the at least one processor 30 may optionally obtain stored field maps and/or gradients or higher order derivatives of field maps to be used to compare to the field map and/or gradients or higher order derivatives of the field map generated at S602. As described above, the field map or the gradients or higher order derivatives may be compared to the data within the databases to find a most similar field map or gradients or higher order derivatives. The field map and/or gradients or higher order derivatives may be stored with resultant encoding direction choices (i.e. scan parameters). Thus, in at least one example embodiment the scan parameters for a particular patient whose field map is generated at S602 may be determined from the scan parameters of a most similar field map or gradients or higher order derivatives stored in the database.

At S804 a distortion forecast map may be obtained. A distortion forecast map may illustrate an expected impact of distortions based on various inputs of scan parameters. In particular, expected distortions from a metal implant may be illustrated in a distortion forecast map for various options for scan parameters. The scan parameters may be adjusted to determine a change in the expected distortions from a metal implant to determine optimal scan parameters that minimize the expected distortions from the metal implant. In at least one example embodiment, a distortion forecast map may have voxels skewed from an intended position as a result of inhomogeneity from an implant.

At S806, the at least one processor 30 may determine the scan parameters. The scan parameters may be determined based on a comparison with data stored in a database as described above with reference to S802 and/or may be determined from the distortion forecasting map as described above with reference to S806. In at least one example embodiment, the method 600 may not perform either or both of the steps S802 and S804. Instead, the scan parameters may be determined at S806 from the field map and/or the gradients or higher order derivatives without comparison to previously obtained field maps and/or gradients or higher order derivatives and without analysis of a distortion forecasting map. For example, an operator and/or algorithm may determine scan parameters based on observation of the field map and/or the gradients or higher order derivatives of the field map.

In at least one example embodiment, determining the scan parameters may additionally include performing a scan using the determined scan parameters. Thus, at S808, the at least one processor 30 may communicate with the acquisition device 20 of the system 10 to cause the system 10 to perform imaging using the determined scan parameters. The scan parameters may be configured to mitigate one or more metal distortion levels of an image output of the scan.

The above-described systems and methods provide guidance on optimal scan parameters used to image a patient with a metallic implant. The systems and methods described herein enable encoding directions to be adapted so that regions of high diagnostic relevance are least impacted by artifacts caused by metal implants. Thus, the systems and methods described herein provide improved imaging methods

Example embodiments have been disclosed herein, it should be understood that other variations may be possible. Such variations are not to be regarded as a departure from the spirit and scope of the present disclosure, and all such modifications as would be obvious to one skilled in the art are intended to be included within the scope of the following claims.

### Non-Limiting Illustrative Embodiments

The following is a list of non-limiting illustrative embodiments disclosed herein:

Illustrative embodiment 1 includes a system for determining scan parameters, the system comprising: at least one memory configured to store instructions; and at least one processor configured to execute the instructions to cause the system to perform a distortion mapping sequence to generate a field map, the field map including spatial information related to anticipated distortions caused by variations of a static magnetic field, process the field map by calculating at least one of a gradient or a higher order derivative of the field map, and determine the scan parameters based on the field map and the at least one of the gradient or the higher order derivative of the field map.

Illustrative embodiment 2 includes the system of illustrative embodiment 1, wherein the scan parameters include at least one of a phase encoding direction, a frequency encoding direction, a slice encoding direction, a type of fat-saturation, a scan prioritization, or B0 and B1 shimming parameters, the type of fat-saturation including at least one of short tau inversion recovery (“STIR”) or spectral-fat-saturation and the scan prioritization including spectral coverage or slice coverage.

Illustrative embodiment 3 includes the system of illustrative embodiment 1 or 2, wherein the at least one processor is configured to execute the instructions to further cause the system to generate a localizer image based on a localizer scan; and generate a graphical representation of the field map by overlaying the at least one of the gradient or the higher order derivative of the field map on the localizer image.

Illustrative embodiment 4 includes the system of any one of illustrative embodiments 1, 2, or 3, wherein the at least one processor is further configured to cause the system to determine the scan parameters by determining mean field map gradients in each of an x-direction, y-direction and z-direction; and assigning at least one of a phase encoding direction, a frequency encoding direction, or a slice encoding direction based on the mean field map gradients.

Illustrative embodiment 5 includes the system of illustrative embodiment 4, wherein the at least one processor is further configured to cause the system to determine the mean field map gradients based on a weighting function.

Illustrative embodiment 6 includes the system of any one of illustrative embodiments 1, 2, 3, 4, or 5, wherein the at least one processor is further configured to cause the system to compare the field map to a plurality of stored field maps in a database; and determine the scan parameters based on the comparison of the field map to the plurality of stored field maps in the database.

Illustrative embodiment 7 includes the system of any one of illustrative embodiments 1, 2, 3, 4, 5, or 6, wherein the at least one processor is further configured to cause the system to compare the at least one of the gradient or the higher order derivative of the field map to a plurality of gradients and higher order derivatives of field maps in a database.

Illustrative embodiment 8 includes the system of illustrative embodiment 7, wherein the at least one processor is further configured to cause the system to determine the scan parameters based on the comparison of the at least one of the gradient or the higher order derivative of the field map to the plurality of gradients and the higher order derivatives of field maps in the database.

Illustrative embodiment 9 includes the system of any one of illustrative embodiments 1, 2, 3, 4, 5, 6, or 7, wherein the at least one processor is further configured to cause the system to output at least one distortion forecast map, the at least one distortion map illustrating an expected impact of metal distortions based on various options for the scan parameters, wherein the at least one processor is further configured to cause the system to determine the scan parameters based on the at least one distortion forecast map.

Illustrative embodiment 10 includes the system of any one of illustrative embodiments 1, 2, 3, 4, 5, 6, 7, 8, or 9, wherein the at least one processor is further configured to cause the system to perform a scan using the scan parameters, wherein the scan parameters are configured to mitigate one or more metal distortion levels of an image output of the scan.

Illustrative embodiment 11 includes a method for determining scan parameters, the method comprising: performing a distortion mapping sequence to generate a field map, the field map including spatial information related to anticipated distortions caused by variations of a static magnetic field; processing the field map by calculating at least one of a gradient or a higher order derivative of the field map; and determining the scan parameters based on the field map and the at least one of the gradient or the higher order derivative of the field map.

Illustrative embodiment 12 includes the method of illustrative embodiment 11, wherein the scan parameters include at least one of a phase encoding direction, frequency encoding direction, slice encoding directions, a type of fat-saturation, a scan prioritization, or B0 and B1 shimming parameters, the type of fat-saturation including at least one of short tau inversion recovery (“STIR”) or spectral-fat-saturation and the scan prioritization including spectral coverage or slice coverage.

Illustrative embodiment 13 includes the method of any one of illustrative embodiment 11 or 12, further comprising: generating a localizer image based on a localizer scan; and generating a graphical representation of the field map by overlaying the at least one of the gradient or the higher order derivative of the field map on the localizer image.

Illustrative embodiment 14 includes the method of any one of illustrative embodiments 11, 12, or 13, wherein the determining the scan parameters includes determining mean field map gradients in each of an x-direction, y-direction and z-direction; and assigning at least one of a phase encoding direction, a frequency encoding direction, or a slice encoding direction based on the mean field map gradients.

Illustrative embodiment 15 includes the method of illustrative embodiment 14, wherein the determining the mean field map gradients is based on a weighting function.

Illustrative embodiment 16 includes the method of any one of illustrative embodiments 11, 12, 13, 14, or 15, further comprising: comparing the field map to a plurality of stored field maps in a database; and determining the scan parameters based on the comparison of the field map to the plurality of stored field maps in the database.

Illustrative embodiment 17 includes the method of any one of illustrative embodiments 11, 12, 13, 14, 15, or 16 further comprising: comparing the at least one of the gradient or the higher order derivative of the field map to a plurality of gradients and higher order derivatives of field maps in a database.

Illustrative embodiment 17 includes the method of illustrative embodiment 16, wherein the determining the scan parameters is further based on the comparison of the at least one of the gradient or the higher order derivative of the field map to the plurality of gradients and higher order derivatives of field maps in the database.

Illustrative embodiment 18 includes the method of any one of illustrative embodiments 11, 12, 13, 14, 15, 16, or 17, further comprising: outputting at least one distortion forecast map, the at least one distortion forecast map illustrating an expected impact of metal distortions based on various options for the scan parameters, wherein the determining the scan parameters is further based on the at least one distortion forecast map.

Illustrative embodiment 20 includes the method of any one of illustrative embodiments 11, 12, 13, 14, 15, 16, 17, 18, or 19, further comprising: performing a scan using the scan parameters, wherein the scan parameters are configured to mitigate one or more metal distortion levels of an image output of the scan.

We claim:

1. A system for determining scan parameters, the system comprising:
at least one memory configured to store instructions; and
at least one processor configured to execute the instructions to cause the system to
perform a distortion mapping sequence to generate a field map, the field map including spatial information related to anticipated distortions caused by variations of a static magnetic field,
process the field map by calculating at least one of a gradient or a higher order derivative of the field map, and
determine the scan parameters based on the field map and the at least one of the gradient or the higher order derivative of the field map.

2. The system of claim 1, wherein the scan parameters include at least one of a phase encoding direction, a frequency encoding direction, a slice encoding direction, a type of fat-saturation, a scan prioritization, or B0 and B1 shimming parameters, the type of fat-saturation including at least one of short tau inversion recovery (“STIR”) or spectral-fat-saturation and the scan prioritization including spectral coverage or slice coverage.

3. The system of claim 1, wherein the at least one processor is configured to execute the instructions to further cause the system to
generate a localizer image based on a localizer scan; and
generate a graphical representation of the field map by overlaying the at least one of the gradient or the higher order derivative of the field map on the localizer image.

4. The system of claim 1, wherein the at least one processor is further configured to cause the system to determine the scan parameters by
determining mean field map gradients in each of an x-direction, y-direction and z-direction; and
assigning at least one of a phase encoding direction, a frequency encoding direction, or a slice encoding direction based on the mean field map gradients.

5. The system of claim 4, wherein the at least one processor is further configured to cause the system to determine the mean field map gradients based on a weighting function.

6. The system of claim 1, wherein the at least one processor is further configured to cause the system to
compare the field map to a plurality of stored field maps in a database; and
determine the scan parameters based on the comparison of the field map to the plurality of stored field maps in the database.

7. The system of claim 1, wherein the at least one processor is further configured to cause the system to
compare the at least one of the gradient or the higher order derivative of the field map to a plurality of gradients and higher order derivatives of field maps in a database.

8. The system of claim 7, wherein the at least one processor is further configured to cause the system to determine the scan parameters based on the comparison of the at least one of the gradient or the higher order derivative of the field map to the plurality of gradients and the higher order derivatives of field maps in the database.

9. The system of claim 1, wherein the at least one processor is further configured to cause the system to
output at least one distortion forecast map, the at least one distortion forecast map illustrating an expected impact of metal distortions based on various options for the scan parameters,
wherein the at least one processor is further configured to cause the system to determine the scan parameters based on the at least one distortion forecast map.

10. The system of claim 1, wherein the at least one processor is further configured to cause the system to
perform a scan using the scan parameters, wherein the scan parameters are configured to mitigate one or more metal distortion levels of an image output of the scan.

11. A method for determining scan parameters, the method comprising:
performing a distortion mapping sequence to generate a field map, the field map including spatial information related to anticipated distortions caused by variations of a static magnetic field;
processing the field map by calculating at least one of a gradient or a higher order derivative of the field map; and
determining the scan parameters based on the field map and the at least one of the gradient or the higher order derivative of the field map.

12. The method of claim 11, wherein the scan parameters include at least one of a phase encoding direction, frequency encoding direction, slice encoding directions, a type of fat-saturation, a scan prioritization, or B0 and B1 shimming parameters, the type of fat-saturation including at least one of short tau inversion recovery (“STIR”) or spectral-fat-saturation and the scan prioritization including spectral coverage or slice coverage.

13. The method of claim 11, further comprising:
generating a localizer image based on a localizer scan; and
generating a graphical representation of the field map by overlaying the at least one of the gradient or the higher order derivative of the field map on the localizer image.

14. The method of claim 11, wherein the determining the scan parameters includes
determining mean field map gradients in each of an x-direction, y-direction and z-direction; and
assigning at least one of a phase encoding direction, a frequency encoding direction, or a slice encoding direction based on the mean field map gradients.

15. The method of claim 14, wherein the determining the mean field map gradients is based on a weighting function.

16. The method of claim 11, further comprising:
comparing the field map to a plurality of stored field maps in a database; and
determining the scan parameters based on the comparison of the field map to the plurality of stored field maps in the database.

17. The method of claim 11, further comprising:
comparing the at least one of the gradient or the higher order derivative of the field map to a plurality of gradients and higher order derivatives of field maps in a database.

18. The method of claim 17 wherein the determining the scan parameters is further based on the comparison of the at least one of the gradient or the higher order derivative of the field map to the plurality of gradients and higher order derivatives of field maps in the database.

19. The method of claim 11, further comprising:
outputting at least one distortion forecast map, the at least one distortion forecast map illustrating an expected impact of metal distortions based on various options for the scan parameters,
wherein the determining the scan parameters is further based on the at least one distortion forecast map.

20. The method of claim 11, further comprising:
performing a scan using the scan parameters, wherein the scan parameters are configured to mitigate one or more metal distortion levels of an image output of the scan.
